(19) United States
(12) Patent Application Publication
(10) Pub. No.: US 2016/0091413 A1
(43) Pub. Date: Mar. 31, 2016

(54) SENSOR FOR MONITORING CORROSION AND METHOD OF MANUFACTURING THE SAME

(71) Applicant: KOREA ELECTRIC POWER CORPORATION, Naju-si (KR)

(72) Inventors: Do-Hyung KIM, Daejeon (KR); Joon-Young SOH, Daejeon (KR); Kyong-Ok KIM, Daejeon (KR)

(21) Appl. No.: 14/869,937

(22) Filed: Sep. 29, 2015

(30) Foreign Application Priority Data
Sep. 29, 2014 (KR) 10-2014-0129880

(51) Int. Cl. G01N 17/04; G01R 19/25; G01N 17/02

(52) U.S. Cl. CPC G01N 17/04; G01N 17/02; G01R 19/25

(57) ABSTRACT

There are provided a sensor for monitoring corrosion, including: a sensor case, and a probe unit installed on one side of an interior of the sensor case and simultaneously measuring deterioration in a coating film of a structure and a rate of consumption of a sacrificial anode of the structure, and a method of manufacturing the same.

### CROSS-REFERENCE TO RELATED APPLICATION

This application claims the priority and benefit of Korean Patent Application No. 10-2014-0129880 filed on Sep. 29, 2014, with the Korean Intellectual Property Office, the disclosure of which is incorporated herein by reference.

### BACKGROUND

The present inventive concept relates to a sensor for monitoring corrosion and a method of manufacturing the same, and more particularly, to a sensor for monitoring corrosion, able to measure deterioration in a coating film and a rate of consumption of a sacrificial anode, occurring in an underwater portion of an offshore structure below sea level, and a method of manufacturing the same.

In general, anticorrosion measures used on offshore structures such as offshore wind power generators are a surface coating scheme and an electric anticorrosion scheme. Since such offshore structures may be installed in relatively deep water, as compared to land-based structures or coastal structures, considerably high maintenance costs have been incurred in the use of such structures, due to limitations on factors such as ships, manpower, special equipment, working periods, and the like.

More specifically, for example, since offshore wind farms have significantly large and wide extents, visual inspection thereof using boats, ships and the like may be highly restricted, and the ability to undertake visual inspections of structures located below sea level, that is, in an underwater portion, is extremely limited.

In the underwater portion below sea level, such visual inspection may not be smoothly undertaken to lead to difficulties such as the necessity for diagnosing corrosion using divers or special equipment, thereby resulting in an increase in costs.

In order to reduce costs, a system for monitoring corrosion in underwater portions of structures is required and along with monitoring thereof, a diagnostic program is necessary to prevent the diffusion of corrosion.

Considering related-art techniques for monitoring corrosion, there are provided techniques for monitoring corrosion potential (please refer to Patent Documents EP 1693664, WO 2006/135391, U.S. Pat. No. 6,902,661 and the like). The techniques are mostly applied to steel and are mainly configured of technologies for analyzing surface states of steel by measuring a corrosion potential thereof. To apply the techniques to coating films to be located underwater, below sea level, may be practically difficult because potential characteristics are varied depending on types of respective coating films.

Next, there are provided techniques for monitoring a corrosion rate (please refer to Patent Documents, U.S. Pat. No. 6,419,817, KR 2014-0028958, and the like). In the techniques, an electrical resistance (ER) or linear polarization resistance (LPR) sensor is mainly used, and after applying a constant level of voltage or current to an electrode, consequent variations in the current may be measured to calculate a corrosion rate. The majority of the measurement methods have been used in the measurement of corrosion states of steel, rather than in analyzing the deterioration of coating films.

In addition, as other techniques for monitoring corrosion, there are provided electrochemical impedance measurement methods (please refer to Patent Documents, WO 2009/049125, US 2005-0212534, U.S. Pat. No. 6,911,828, KR 2010-0105651, and the like). The measurement methods require devices such as a voltage input device, a frequency converter, a frequency analyzer, and the like, and thus, may be disadvantageous, in that an overall configuration thereof may be complicated and deterioration in coating films may be accelerated due to an AC voltage input thereto.

Finally, there are provided electrochemical noise measurement methods (please refer to Patent Documents, WO 2002/073169, U.S. Pat. No. 6,294,074, U.S. Pat. No. 5,888,374, U.S. Pat. No. 6,478,948, and the like). The greatest features of the measurement methods are to analyze corrosion states by only processing voltage and current signals without an external input device.

However, considering the techniques for monitoring corrosion according to the related art, the techniques relate to methods of measuring corrosion states or corrosion rates of steel, rather than coating films.

Some of the electrochemical impedance measurement methods have suggested techniques for monitoring localized corrosion and deterioration of coating films; however, such electrochemical impedance measurement methods require external input devices and frequency analyzing devices as described above, thereby causing limitations such as the consumption of power and complexity in measurement devices. In addition, deterioration in the coating films may be relatively accelerated due to an AC voltage input from the outside.

In addition, the majority of the electrochemical noise measurement methods deal with sensors and signal processing methods that are restricted to localized corrosion occurring in boilers or atomic apparatuses, and have not yet been applied to the underwater portions of structures disposed below sea level.

### SUMMARY

An aspect of the present inventive concept may provide a sensor for monitoring corrosion, able to measure deterioration in a coating film and a rate of consumption of a sacrificial anode, occurring in an underwater portion of an offshore structure below sea level, and a method of manufacturing the same.

According to an aspect of the present inventive concept, a sensor for monitoring corrosion may include: a sensor case, and a probe unit installed on one side of an interior of the sensor case and simultaneously measuring deterioration in a coating film of a structure and a rate of consumption of a sacrificial anode of the structure.

According to another aspect of the present inventive concept, a method of manufacturing a sensor for monitoring corrosion may include: molding a probe unit simultaneously measuring deterioration in a coating film of a structure and a rate of consumption of a sacrificial anode of the structure; and coupling the probe unit completed to a sensor case.

### BRIEF DESCRIPTION OF DRAWINGS

The above and other aspects, features and advantages of the present inventive concept will be more clearly understood from the following detailed description taken in conjunction with the accompanying drawings, in which:

FIG. 1 is a perspective view illustrating a coating film probe of a sensor for monitoring corrosion according to an exemplary embodiment of the present inventive concept;

FIG. 2 is a perspective view illustrating a sacrificial anode probe of the sensor for monitoring corrosion according to an exemplary embodiment of the present inventive concept;

FIG. 3 is a plan view schematically illustrating a holder used in a method of manufacturing the sensor for monitoring corrosion according to an exemplary embodiment of the present inventive concept;

FIG. 4 is a view schematically illustrating a molding process in the method of manufacturing the sensor for monitoring corrosion according to an exemplary embodiment of the present inventive concept;

FIG. 5 is a front view illustrating a probe unit of the sensor for monitoring corrosion according to an exemplary embodiment of the present inventive concept;

FIG. 6 is a cross-sectional view, taken along line A-A′ of FIG. 5;

FIG. 7 is a cross-sectional view, taken along line B-B′ of FIG. 5;

FIG. 8 is a front view illustrating a sensor for monitoring corrosion according to an exemplary embodiment of the present inventive concept;

FIG. 9 is a cross-sectional view, taken along line C-C′ of FIG. 8; and

FIG. 10 is a block diagram schematically illustrating a configuration of a signal processing unit of the sensor for monitoring corrosion according to an exemplary embodiment of the present inventive concept.

### DETAILED DESCRIPTION

Exemplary embodiments of the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements maybe exaggerated for clarity, and the same reference numerals will be used throughout to designate the same or like elements.

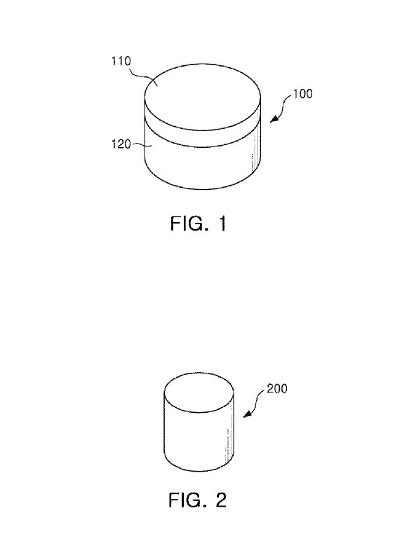

FIG. 1 is a perspective view illustrating a coating film probe of a sensor for monitoring corrosion according to an exemplary embodiment of the present inventive concept. A coating film probe 100 may be configured by processing a body portion 120 formed of a material the same as a material (for example, a steel or the like) constituting an offshore structure, in a tubular shape or a pillar shape, and forming a coating film portion 110 through coating a coating film used in the offshore structure on one surface of the body portion 120. The coating film probe 100 configured as above may indicate deterioration in the coating film of the offshore structure and at the same time, may determine a corrosion rate of the body portion 120 to calculate a residual corrosion tolerance thickness at the time of the termination of deterioration of the coating film portion 110.

FIG. 2 is a perspective view illustrating a sacrificial anode probe of the sensor for monitoring corrosion according to an exemplary embodiment of the present inventive concept. Below sea level, a sacrificial anode is typically formed of aluminum, an aluminum-zinc alloy, magnesium or the like. Thus, a sacrificial anode probe 200 may be manufactured by processing a material the same as that used as a sacrificial anode in an undersea portion of an offshore structure, in a tubular shape or a pillar shape.

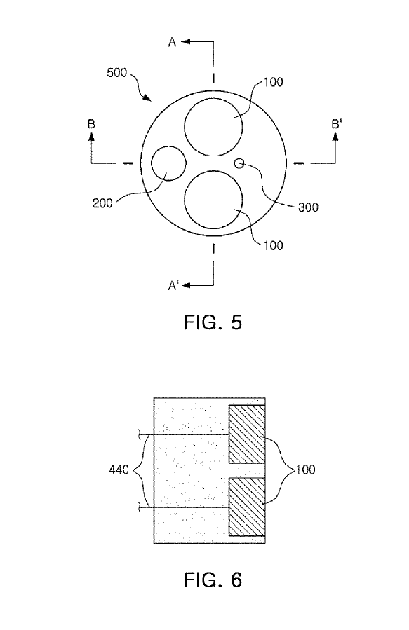

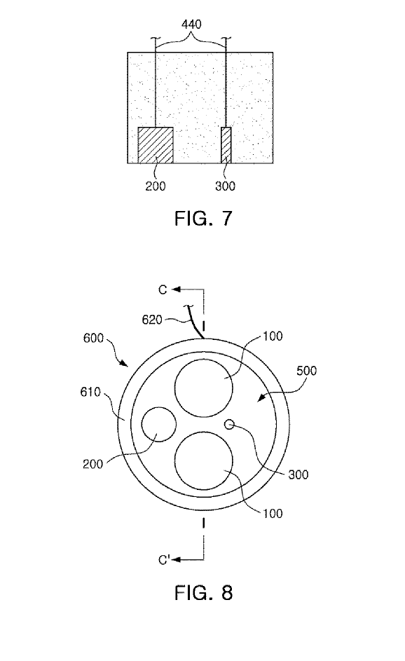

Although not separately illustrated, a reference electrode 300 (Please refer to FIG. 4, FIG. 5, FIG. 7, and FIG. 8) for providing a reference potential in measuring potentials may be provided. The reference electrode 300 may be formed of, for example, silver (Ag), platinum (Pt) or the like.

FIG. 4 is a view schematically illustrating a molding process in the method of manufacturing the sensor for monitoring corrosion according to an exemplary embodiment of the present inventive concept. As illustrated in FIG. 4, the coating film probe 100, the sacrificial anode probe 200, and the reference electrode 300, separately manufactured, are fixed to a mold 410, and a molding resin 430 prepared in a resin-mixing bath 420 may be injected into the mold 410 to mold a probe unit. In this case, signal lead wires 440 may be molded to protrude outwardly from the probe unit, thereby allowing the application of power or the transmission of a signal to be smoothly performed.

As the resin, a material having a significantly low shrinkage rate at the time of solidification in order to minimize corrosion or the like, in a gap of an edge portion, as well as having superior waterproofing properties and chemical-resistance properties and a high degree of resistance to the infiltration of seawater, may be selected. For example, an acrylic resin or an epoxy resin may be selected.

When the resin is cured, it may be drawn out of the mold 410, thereby obtaining a probe unit 500 having the coating film probe 100, the sacrificial anode probe 200, and the reference electrode 300 integrated with one another, as illustrated in FIG. 5.

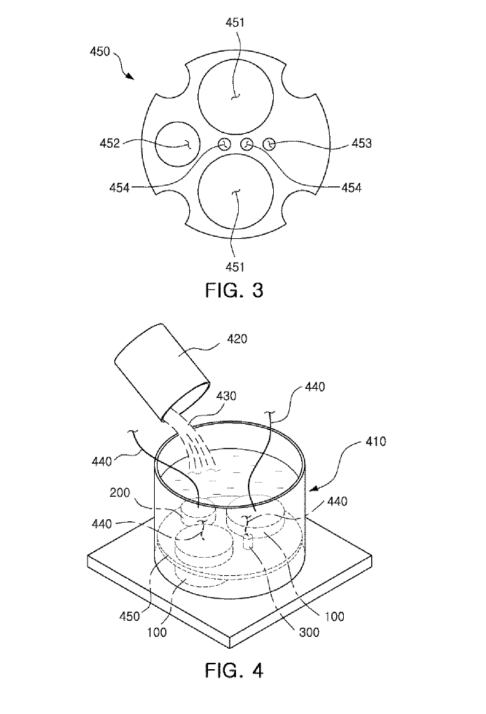

Meanwhile, during the molding process, a holder for fixing the coating film probe 100, the sacrificial anode probe 200, and the reference electrode 300 may be used. FIG. 3 is a plan view schematically illustrating a holder used in a method of manufacturing the sensor for monitoring corrosion according to an exemplary embodiment of the present inventive concept.

As illustrated in the exemplary embodiment, a holder 450 may be provided with a coating film probe opening 451 for the coating film probe 100, a sacrificial anode probe opening 452 for the sacrificial anode probe 200, and a reference electrode opening 453 for the reference electrode 300. The openings may serve to fix the coating film probe 100, the sacrificial anode probe 200, and the reference electrode 300 at regular intervals during molding.

Through holes 454 formed in a central portion of the holder 450 may allow gas bubbles or the like to be easily expelled from the resin during molding. In addition, the holder 450 may have a size or a shape to form a gap or space between the mold 410 and the holder 450 in order to facilitate the injection of resin during molding. The holder 450 may be formed of a material having no electrical conductivity and for example, may preferably be formed of a highly chemical-resistant material such as fluorine plastics.

FIG. 5 is a front view illustrating a probe unit of the sensor for monitoring corrosion according to an exemplary embodiment of the present inventive concept. FIG. 6 is a cross-sectional view, taken along line A-A′ of FIG. 5. FIG. 7 is a cross-sectional view, taken along line B-B′ of FIG. 5. As illustrated in the drawings, the sensor for monitoring corrosion according to an exemplary embodiment of the present inventive concept may include the probe unit 500 formed by integrally molding at least one coating film probe 100 having the coating film portion 110 formed through coating a coating film used in a structure (not shown); at least one sacrificial anode probe 200 formed of a material the same as that of a sacrificial anode of the structure; and the reference electrode 300 for providing a reference potential.

The signal lead wires 440 are respectively connected to the individual coating film probe 100, sacrificial anode probe 200 and reference electrode 300, and may protrude outwardly from the probe unit 500 as described above, thereby allowing the application of power or the transmission of a signal to be smoothly performed.

In addition, one surfaces of the coating film probe 100, the sacrificial anode probe 200, and the reference electrode 300 may be configured to be exposed from the probe unit 500, such that a surface area of the probe may be accurately calculated, in measuring deterioration of the coating film and a rate of consumption of the sacrificial anode.

Although FIG. 3 through FIG. 9 illustrate an example of the probe unit 500 including a pair of coating film probes 100, a single sacrificial anode probe 200, and a single reference electrode 300, the number of the probes 100 and 200 are not limited thereto and if necessary, may be further increased within a single probe unit 500.

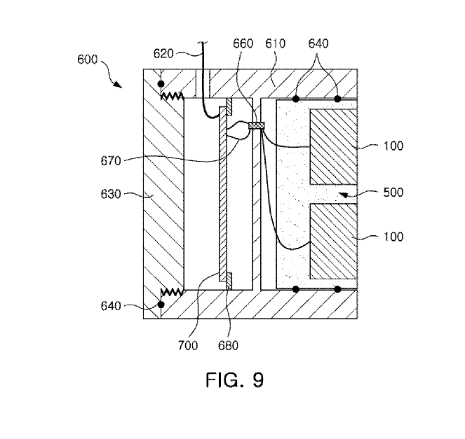

FIG. 8 is a front view illustrating a sensor for monitoring corrosion according to an exemplary embodiment of the present inventive concept. FIG. 9 is a cross-sectional view, taken along line C-C′ of FIG. 8. As illustrated in the drawings, a sensor 600 for monitoring corrosion according to an exemplary embodiment of the present inventive concept may include the probe unit 500, a sensor case 610, a communications line 620, and a signal processing unit 700.

The sensor case 610 may be provided to protect the probe unit 500, signal lead wires 440 and 670, the signal processing unit 700 and the like, from the seawater. The sensor case 610 may be a member formed in a substantially tubular or pipe shape, using a material such as fiber reinforced plastics (FRP), fluorine plastics or the like.

When the probe unit 500 is completed and prepared, the probe unit 500 may be coupled to an opening of the sensor case 610 and in this case, a space between the probe unit 500 and the sensor case 610 may be water-tightly sealed using a sealing member 640, such as an O-ring, thereby preventing the infiltration of seawater.

The signal lead wire 440 of the probe unit 500 may be connected to a cable connector 660 and the signal lead wire 670 drawn-out from the cable connector 660 may be connected to the signal processing unit 700. However, the cable connector may be omitted or may be replaced with another electrical connection means.

Accordingly, the probe unit 500 may be electrically connected to the signal processing unit 700 via the signal lead wire or the cable connector, and a signal having been processed by the signal processing unit may deliver information relating to corrosion in an offshore structure via the communications line 620.

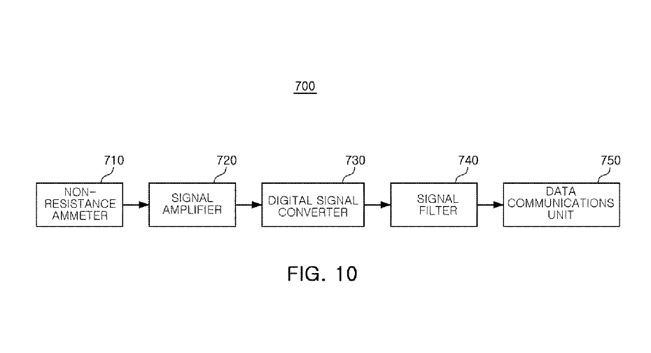

FIG. 10 is a block diagram schematically illustrating a configuration of a signal processing unit of the sensor for monitoring corrosion according to an exemplary embodiment of the present inventive concept. As illustrated in FIG. 10, the signal processing unit 700 may include a non-resistance ammeter 710 measuring a current or a voltage of the coating film probe 100, the sacrificial anode probe 200, or the reference electrode 300; a signal amplifier 720 amplifying a current or voltage signal input through the non-resistance ammeter 710; an analog to digital signal converter 730 converting the amplified signal into a digital signal; a signal filter 740 filtering the converted digital signal; and a data communications unit 750 transmitting the filtered signal to a user.

The signal processing unit 700 may be formed of, for example, a printed circuit board (PCB) and preferably, may be embedded in the sensor 600 for monitoring corrosion, itself, so as to minimize the influence of noise, but is not limited thereto.

In addition, a plurality of signal processing units 700 may be provided, and example, one pair of the coating film probes 100 and the reference electrode 300 may be connected to one signal processing unit 700 to configure a first cell, while another pair of the coating film probes 100, the sacrificial anode probe 200, and the reference electrode 300 may be connected to another signal processing unit 700 to configure a second cell.

The signal processing unit 700 may be mounted on a fixing member 680 provided within the sensor case 610, using a fixing element such as a fixing screw, an adhesive or the like and may secure stability thereof under offshore environmental conditions.

Meanwhile, the sensor case 610 may be provided with a cover 630 for the maintenance of the signal processing unit 700. The cover 630 may be combined with the sensor case 610 in a screw-coupled manner, and it may also be preferable to use the sealing member 640 such as an O-ring in a space between the cover 630 and the sensor case 610 to prevent the infiltration of seawater.

Hereinafter, an operation of the sensor for monitoring corrosion according to an exemplary embodiment of the present inventive concept will briefly be described.

First, in the coating film probe 100 and the sacrificial anode probe 200 exposed to offshore environments, deterioration progresses in the coating film portion 110, and the sacrificial anode probe 200 is gradually consumed over time. Variations in voltage and current may be generated in the both probes. The variations in voltage and current over time may be input to the signal processing unit 700 through the signal lead wire 440, the cable connector 660, and the signal lead wire 670.

After current and voltage signals input to the signal processing unit 700 are processed by the signal processing unit 700, information regarding a rate of progress of deterioration in the coating film and a rate of consumption of the sacrificial anode may be provided to a user via the communications line 620.

As set forth above, according to exemplary embodiments of the present inventive concept, deterioration in a coating film and a rate of consumption of a sacrificial anode, occurring in an underwater portion of an offshore structure below sea level, for example, may be simultaneously measured, using a simply configured sensor for monitoring corrosion.

In addition, according to exemplary embodiments of the present inventive concept, a sensor for monitoring corrosion may be manufactured through a simple and inexpensive process.

While exemplary embodiments have been shown and described above, it will be apparent to those skilled in the art that modifications and variations could be made without departing from the scope of the invention as defined by the appended claims.

What is claimed is:

1. A sensor for monitoring corrosion, comprising:
a sensor case, and
a probe unit installed on one side of an interior of the sensor case and simultaneously measuring deterioration in a coating film of a structure and a rate of consumption of a sacrificial anode of the structure.

2. The sensor for monitoring corrosion of claim 1, wherein the probe unit is formed by integrally molding at least one coating film probe having a coating film portion formed through coating the coating film used in the structure; at least one sacrificial anode probe formed of a material the same as that of the sacrificial anode of the structure; and a reference electrode for providing a reference potential.

3. The sensor for monitoring corrosion of claim 2, wherein the coating film portion of the coating film probe is formed on one surface of a body portion formed of the same material as a material constituting the structure.

4. The sensor for monitoring corrosion of claim 2, wherein signal lead wires are respectively connected to the coating film probe, sacrificial anode probe and reference electrode.

5. The sensor for monitoring corrosion of claim 4, wherein the sensor case includes a signal processing unit therein, and
the signal lead wires are electrically connected to the signal processing unit.

6. The sensor for monitoring corrosion of claim 5, wherein the sensor case is provided with a cover for maintenance of the signal processing unit.

7. The sensor for monitoring corrosion of claim 5, wherein the signal processing unit includes:
a non-resistance ammeter measuring a current or a voltage of the coating film probe, the sacrificial anode probe, or the reference electrode;
a signal amplifier amplifying a current or voltage signal input through the non-resistance ammeter;
an analog to digital signal converter converting the amplified signal into a digital signal;
a signal filter filtering the converted digital signal; and
a data communications unit transmitting the filtered signal.

8. The sensor for monitoring corrosion of claim 1, wherein a sealing member is interposed between the probe unit and the sensor case.

9. A method of manufacturing a sensor for monitoring corrosion, comprising:
molding a probe unit simultaneously measuring deterioration in a coating film of a structure and a rate of consumption of a sacrificial anode of the structure; and
coupling the probe unit completed to a sensor case.

10. The method of claim 9, wherein the molding includes :
preparing a coating film probe;
preparing a sacrificial anode probe;
preparing a reference electrode;
disposing the coating film probe, the sacrificial anode probe, and the reference electrode within a mold; and
injecting a resin into the mold.

11. The method of claim 10, wherein the preparing of the coating film probe includes:
forming a body portion using the same material as a material constituting the structure; and
forming a coating film portion through coating a coating film used in the structure on one surface of the body portion.

12. The method of claim 10, wherein in the preparing of the sacrificial anode probe,
the sacrificial anode probe is formed using a material the same as that used as a sacrificial anode of the structure.

13. The method of claim 10, wherein in the disposing,
a holder for fixing the coating film probe, the sacrificial anode probe, and the reference electrode is used.

14. The method of claim 13, wherein the holder is provided with a coating film probe opening for the coating film probe, a sacrificial anode probe opening for the sacrificial anode probe, and a reference electrode opening for the reference electrode.

15. The method of claim 10, wherein the molding further includes: connecting signal lead wires to the coating film probe, sacrificial anode probe and reference electrode, respectively, and
the signal lead wires are molded to protrude outwardly from the probe unit.

16. The method of claim 15, further comprising: installing a signal processing unit within the sensor case; and
electrically connecting the signal lead wires to the signal processing unit.

17. The method of claim 9, further comprising: sealing a space between the probe unit and the sensor case.
